(19) United States
(12) Patent Application Publication
(10) Pub. No.: US 2011/0259388 A1
(43) Pub. Date: Oct. 27, 2011

(54) Photovoltaic Receiver

(75) Inventors: Joseph C. Krauskopf, Portola Valley, CA (US); Manoj Nachnani, Los Altos, CA (US)

(73) Assignee: CHROMASUN PTY LTD, New South Wales (AU)

(21) Appl. No.: 13/126,432

(22) PCT Filed: Oct. 30, 2009
(86) PCT No.: PCT/AU2009/001422

§ 371 Date: Apr. 27, 2011

Related U.S. Application Data
(60) Provisional application No. 61/110,109, filed on Oct. 31, 2008.

(51) Int. Cl. H01L 31/0224; H01L 31/18

(52) U.S. Cl. 136/244; 438/66; 257/E31.124

(57) ABSTRACT

A PV receiver that, when located within a solar concentrator, provides for shielding of electrical connections associated with the receiver from solar radiation that is reflected toward the receiver. The PV receiver comprises an electrically non-conductive elongate carrier, and a plurality of PV wafer dice mounted as a linear array to a first, forward, face of the carrier. A plurality of conductor elements is arrayed along the first face of the carrier behind the PV wafer dice and the conductor elements are connected one-to-one with electrodes located on a first, rearward, face of each of the wafer dice. Busbars are located on the elongate carrier behind the PV wafer dice, and electrically conductive connections made between the conductor elements and the busbars behind the PV wafer dice. In one embodiment of the PV receiver the busbars are located on a second, rearward, face of the carrier and the electrically conductive connections are made through the carrier. A method of shielding electrical connections associated with a PV receiver within a solar concentrator from radiation reflected toward the receiver is also disclosed.

### FIELD OF THE INVENTION

This invention relates to a photovoltaic (“PV”) receiver structure that is suitable for use in a solar concentrator and to a method of forming such receiver structure.

### BACKGROUND OF THE INVENTION

International Patent Application No. PCT/AU2009/000529, dated 28 Apr. 2009 (with earliest priority date of 13 May 2008), in the name of Chromasun Pty Ltd, discloses a solar concentrator that comprises a housing structure having a multi-windowed aperture arranged to admit incident solar radiation. A plurality of laterally spaced linearly extending receivers is located within the housing structure, and a plurality of linearly extending reflector elements is associated with respective ones of the receivers and arranged to reflect, toward the respective receivers, incident solar radiation that passes between the spaced-apart receivers. A drive mechanism is provided to impart pivotal (sun tracking) drive to the reflector elements.

In one embodiment of the concentrator as disclosed in the referenced Application, each of the receivers is described in general terms as comprising a linear array of PV chips (referred to herein as “dice”) mounted to a linearly extending carrier and, in progressing development of such receiver, it has been determined that the total effective operating efficiency of the concentrator may be degraded by spillage at the individual receivers of radiation from the associated reflectors. Thus, it has been determined that the receivers should be structured to provide for maximisation of the radiation-absorbing area of the PV dice within the target area irradiated by reflection from the reflectors.

### SUMMARY OF THE PRESENT INVENTION

Broadly defined, the present invention provides a method of shielding electrical connections associated with a PV receiver from incident solar radiation and which comprises: mounting a plurality of PV wafer dice in a linear array to a first, forward, face of an electrically non-conductive elongate carrier, and making electrically conductive connections between electrodes on a first, rearward, face of each of the PV wafer dice and electrical busbars located on the elongate carrier behind the PV wafer dice, the electrically conductive connections being made by way of conductor elements arrayed along the first face of the elongate carrier behind the PV wafer dice.

The invention may also be defined in terms of a PV receiver structure which comprises: an electrically non-conductive elongate carrier, a plurality of PV wafer dice mounted as a linear array to a first, forward, face of the carrier, a plurality of conductor elements arrayed along the first face of the carrier behind the PV wafer dice and connected one-to-one with electrodes located on a first, rearward, face of each of the wafer dice, electrical busbars located on the elongate carrier behind the PV wafer dice, and electrically conductive connections made between the conductor elements and the busbars behind the PV wafer dice.

In use of the invention in its various possible forms, as above defined and described in the following text, the PV wafer dice effectively function to shield electrical connections to the busbars. Thus, no peripheral electrical connections are required and the target area for radiation reflected toward the receiver may be constituted wholly (or substantially wholly) by the arrayed PV wafer dice. An associated advantage flowing from shielding the electrical connections behind the dice, is that peripheral connections, that would otherwise be required, are not present to provide shading of reflectors.

The invention as above defined envisions the employment of an elongate carrier in the form of a single-sided substrate, in which case the conductor elements and the busbars will both be located on the one face, i.e. the first face, of the carrier. In an optionally alternative form of the invention the carrier may comprise a double-sided substrate and, in such case, the busbars may be located on a second, rearward, face of the carrier. Then, the electrically conductive connections between the conductor elements and the busbars will be made through the carrier.

In an embodiment of the invention involving a two-sided carrier, the PV receiver structure may be defined as a PV receiver structure which comprises: an electrically non-conductive elongate carrier, a plurality of PV wafer dice mounted as a linear array to a first, forward, face of the carrier, a plurality of conductor elements arrayed along the first face of the carrier rearwardly of the PV wafer dice and connected one-to-one with electrodes located on a first, rearward, face of each of the wafer dice, busbars extending along a second, rearward, face of the carrier, and conductive connecting elements extending through the carrier and connecting alternate ones of the conductor elements with associated ones of the busbars.

The elongate carrier portion of the receiver structure may optionally be formed from any electrically non-conductive material having a thermal capacity appropriate to a given application. The carrier may comprise, for example, a rigid or semi-rigid printed circuit board but, in one embodiment of the invention, the carrier desirably comprises a flexible substrate on which the conductor elements and busbars are formed as “printed” copper regions by a PCB fabrication technique known in, for example, the PC packaging art. A carrier that has been found suitable for use in one embodiment of the invention comprises a flexible substrate that is clad with copper on both surfaces and on which the conductor elements and busbars are each formed by a subtraction etching process.

The conductor elements to which the electrodes on the rearward faces of the PV wafer dice are connected may optionally have any form that is suitable for one-to-one contact with the dice electrodes. Thus, each conductor element may optionally comprise a small copper pad having, for example, a circular or square shape. However, in a case of electrodes that extend transversely as fingers or traces across the rearward face of the PV wafer die, the conductor elements may be formed (i.e., printed) as copper stripes and extend transversely across at least a portion of the width of the carrier. In this latter case, each conductor element will have a width (in the longitudinal direction of the carrier) that is approximately the same as the width of the finger with which it connects.

The one-to-one connections between the electrodes and the conductor elements may optionally be made by use of a wholly-metal solder but, in the interest of constraining flow, the connections desirably are made by use of an epoxy solder paste. The solder paste may be deposited in a more-or-less conventional manner, using a screen printing process, and be oven cured, again using procedures known in the art.

The conductive connector elements that are employed, in one embodiment of the invention, for connecting the conductor elements to the busbars desirably are formed in the same manner as conventional vias; that is by way of copper-filled drill holes.

The PV wafer dice that are mounted, as a linear array, to the carrier may optionally be cut from a polycrystalline silicon wafer but, in the interest of achieving greater conversion efficiency, the wafer dice desirably are cut from a monocrystalline silicon wafer.

The receiver structure as above defined, incorporating the carrier and the PV wafer dice, may, and normally will, be mounted to a thermally conductive elongate support member, for example in the form of a copper or other metal bar, to form a receiver assembly. The mounting may be effected by bonding the carrier to the support member using a thermally conductive, electrically non-conductive adhesive.

The invention will be more fully understood from the following description of an illustrative embodiment of a PV receiver assembly. The description is provided by way of example with reference to the accompanying drawings.

### BRIEF DESCRIPTION OF THE DRAWINGS

FIG. 1 shows a diagrammatic end view of a single receiver assembly and associated reflector elements within the housing of a concentrator,

FIG. 2 shows an inverted perspective view of the receiver assembly and a constituent PV receiver structure,

FIG. 3A shows, on an enlarged scale, a second, forward, face view of a PV wafer die removed from the receiver structure,

FIG. 3B shows a first, rearward, face view of the PV wafer die, also on an enlarged scale,

FIG. 4A shows an exploded perspective view of a portion of a carrier component of the receiver structure and overlying PV wafer die,

FIG. 4B shows on an enlarged scale the region of the carrier that is shown encircled in FIG. 4A,

FIG. 5 shows a rearward face view of a portion of the carrier as seen in the direction of arrow 5 shown in FIG. 4A,

FIG. 6 illustrates electrical connecting arrangements between two PV wafer dice and shows (side-by-side, vertically aligned) forward and rearward face views of a portion of the carrier, and

FIG. 7 shows a schematic representation of electrical connections of three PV wafer dice and a by-pass diode connected across one of the dice.

### DETAILED DESCRIPTION OF EXEMPLARY EMBODIMENT OF THE INVENTION

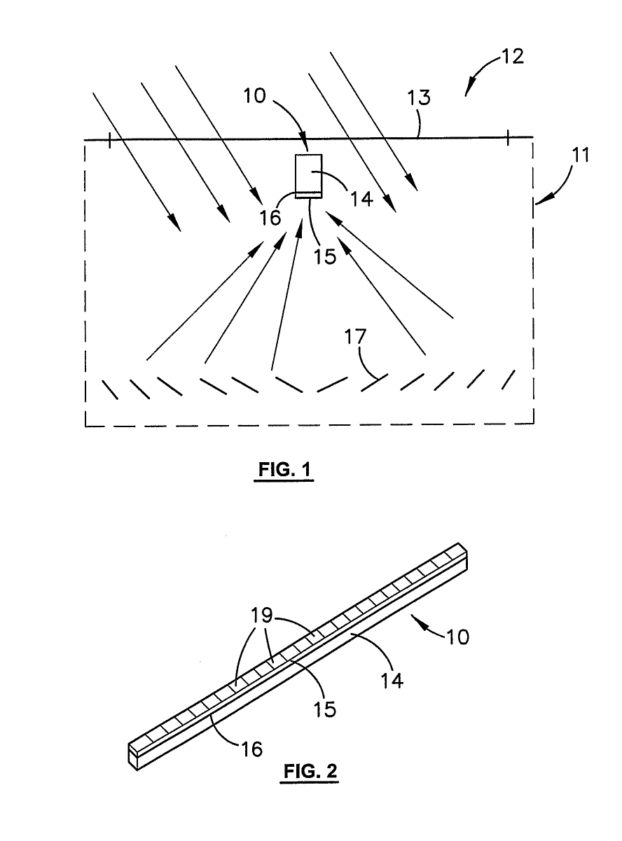

In the diagrammatic illustration of FIG. 1, a single PV receiver assembly 10 is shown located within a housing 11 of a solar concentrator unit 12, although the concentrator unit would more typically house three such receiver assemblies in laterally-spaced relationship. The receiver assembly 10 is located immediately below a windowed aperture 13 of the concentrator unit, and the receiver assembly extends linearly in a north-south direction when the concentrator unit is located in situ, with adjacent receiver assemblies 10 spaced-apart in the east-west direction.

The receiver assembly 10 comprises an elongate metal (typically copper) support member 14 and a receiver structure 15 that is bonded to the support member by a thermal interface material 16 in the form of an adhesive coating. The interface material is selected to accommodate differential thermal expansion between the receiver structure 15 (as a sub-assembly) and the support member 14.

The receiver assembly 10 might typically have a width of the order of 20 mm and a length extending for substantially the full length of the concentrator housing 11, typically of the order of 1.5 m to 4.0 m in the north-south direction.

A group of linearly extending reflectors 17 is associated with and located below the receiver assembly 10 and the reflectors 17 are disposed to reflect upwardly toward the receiver assembly incident solar radiation that passes downwardly between the adjacent, laterally spaced receiver assemblies. As illustrated, the group of reflectors comprises twelve reflector elements 17 and they are supported for pivotal (sun tracking) movement in the east-west direction. A drive mechanism (not shown) is located within the housing 11 for imparting pivotal drive to the reflector elements.

Each of the reflector elements 17 has approximately the same length as the receiver assembly 10, and each reflector elements has a transversely curved concentrating profile. The radius of curvature of the reflector elements increases with distance of the reflector elements from the receiver assembly.

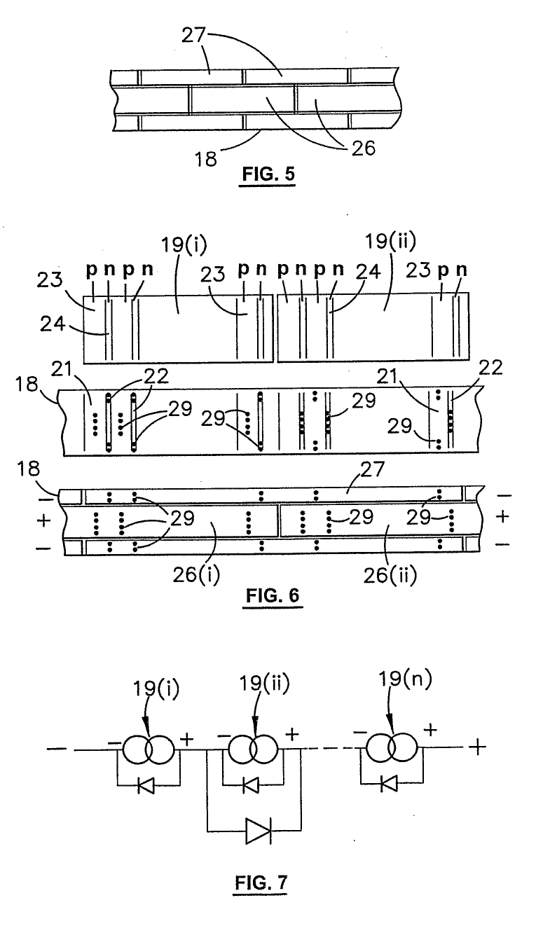

As shown in FIGS. 2 to 6, the receiver structure 15 comprises an electrically non-conductive elongate carrier 18 and a plurality of PV wafer dice 19 mounted as a linear array to a first, forward, face 20 of the carrier 18. Also, as shown in FIGS. 4A,B and 6, a plurality of transversely extending stripe-like conductor elements (or conductive traces) is arrayed along the first face 20 of the carrier rearwardly of the PV wafer dice 19. The conductor elements comprise alternating “wide” and “narrow” conductor elements 21 and 22 and they are connected one-to-one with electrodes 23 and 24 (as below described) that are located on a first, rearward, face 25 of each wafer die 19. Busbars 26 and 27 extend along a second, rearward, face 28 of the carrier 18, as illustrated in FIGS. 5 and 6, and conductive connecting elements 29, as shown in FIG. 6, extend through the carrier to interconnect the conductor elements and busbars 21,26 and 22,27.

The elongate carrier 18 in the illustrative embodiment comprises a flexible PC substrate on which the conductor elements 21,22 and the busbars 26,27 are formed as “printed” copper regions by a subtraction etching process.

The PV wafer dice 19 that are mounted as a linear array to the carrier 18 may, as previously stated, be cut from a polycrystalline silicon wafer but, desirably, are cut from a monocrystalline silicon wafer. Each die has a radiation absorptive forward face 28 and is provided on its rearward face 25 with the electrodes 23 and 24. The electrodes are formed as metallised fingers, and wider ones of the electrodes 23 are coupled into p-doped regions of the die. The alternating narrower electrodes 24 are coupled into n-doped regions of the die.

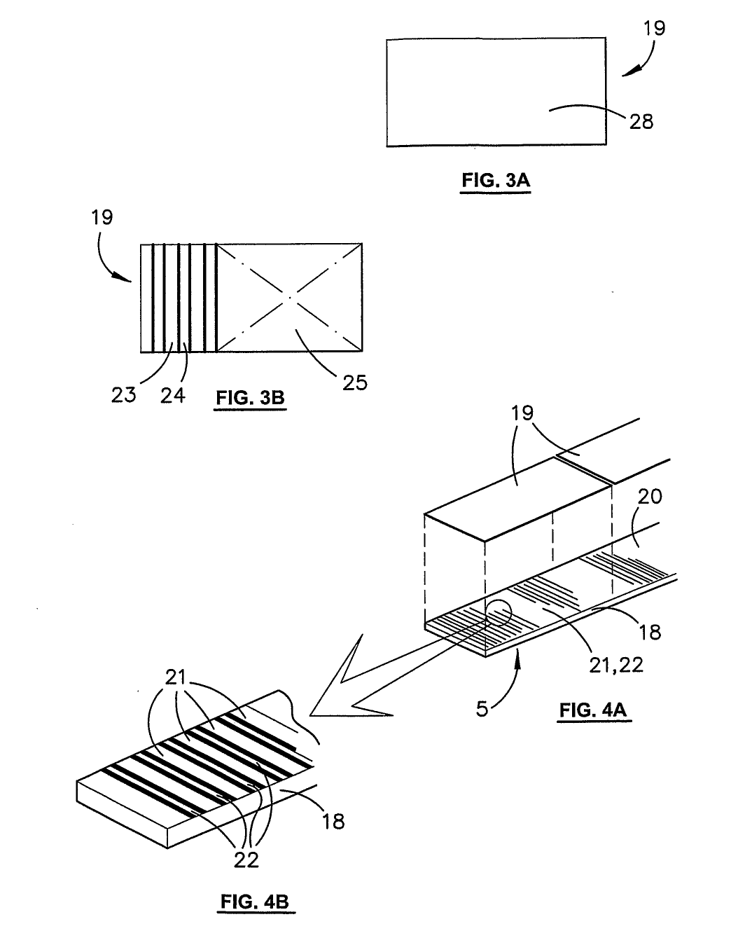

Although only a few of the electrodes 23 and 24 are actually shown in FIG. 3B, the rearward face of each die 19 will typically contain up to about 20 of each of the two (wider and narrower) electrodes. Again although not so shown in FIG. 3B, the electrodes are arrayed along the full length of the die with adjacent electrodes being spaced apart by a small gap that is aligned with the p-n junction between adjacently doped regions of the die.

Although each PV wafer die is (for convenience) shown in the drawings to have a length that is greater than its width, each die might typically have a transverse width of the order of 19 mm to 20 mm and a length of the order of 7 mm. Thus, in the case of a receiver assembly having a total length of 2 m, approximately 280 dice will be mounted to the receiver assembly.

The conductor elements 21 and 22 on the carrier substrate 18 have widths (in the longitudinal direction of the carrier) that match accurately the widths of the dice electrodes 23 and 24 with which they connect. The one-to-one connections between the conductor elements 21,22 and the electrodes 23,24 are made by an epoxy solder paste which is deposited using a screen printing process and is oven cured.

The connector elements 29 (FIG. 6) that are employed to connect the conductor elements 21,22 to the busbars 26,27 are formed as vias (that is, as copper-filled drill holes) and they provide both electrical and thermal conduction paths. The actual connection arrangement to be adopted will be dependent upon electrical output requirements of a given receiver structure (that is, as a series circuit for maximised voltage output or as a parallel circuit for maximised current) and the connections shown in FIGS. 6 and 7 illustrate a series circuit arrangement.

Thus, as represented in FIG. 6, p-coupled electrodes 23 of the two dice 19(i) and 19(ii) are solder-connected to corresponding (wider) conductor elements 21 on the carrier 18, and n-coupled electrodes 24 of the two dice 19(i) and 19(ii) are solder-connected to corresponding (narrower) conductor elements 22 on the carrier 18.

Then, the wider conductor elements 21 along the length of the carrier 18 that is overlaid by the die 19(i) are connected by the connector elements 29 to the underlying (rearward) busbar portion 26(i), and the narrower conductor elements 22 on the length of the carrier that is overlaid by the die 19(i) are connected by the connector elements 29 to the two underlying (rearward) busbar portions 27. Conversely, the wider conductor elements 21 on the length of the carrier that is overlaid by the die 19(ii) are connected by the connector elements 29 to the underlying two (rearward) busbar portions 27, and the narrower conductor elements 22 on the length of the carrier that is overlaid by the die 19(ii) are connected by the connector elements 29 to the underlying (rearward) busbar portion 26(ii).

This pattern is repeated for successive pairs of arrayed dice 19(i) and 19(ii) for the full length of the carrier 18 and, hence, the full length of the receiver structure; and relevant busbar portions are connected to establish the series circuit illustrated in FIG. 7.

A bypass diode 30 is connected in parallel across selected ones or groups of the dice 19 to protect against fault conditions, and the diode (or each of the diodes) may be pocketed within a recess (not shown) that is formed in the carrier 18.

Variations and modifications may be made in respect of the invention as above described and defined in the following statements of claim.

1. A method of shielding electrical connections associated with a PV receiver within a solar concentrator from radiation reflected toward the receiver and which comprises:
mounting a plurality of PV wafer dice in a linear array to a first, forward, face of an electrically non-conductive elongate carrier, and making electrically conductive connections between electrodes on a first, rearward, face of each of the PV wafer dice and electrical busbars located on the elongate carrier behind the PV wafer dice, the electrically conductive connections being made by way of conductor elements arrayed along the first face of the elongate carrier behind the PV wafer dice.

2. The method as claimed in claim 1 wherein the elongate carrier is in the form of a single-sided substrate and wherein the conductor elements and the busbars are both located on the first face of the elongate carrier.

3. The method as claimed in claim 1 wherein the carrier is in the form of a double-sided substrate, wherein the busbars are located on a second face of the elongate carrier and the electrically conductive connections between the conductor elements and the busbars are made through the elongate carrier.

4. A PV receiver structure which comprises:
an electrically non-conductive elongate carrier,
a plurality of PV wafer dice mounted as a linear array to a first, forward, face of the carrier,
a plurality of conductor elements arrayed along the first face of the carrier behind the PV wafer dice and connected one-to-one with electrodes located on a first, rearward, face of each of the wafer dice, electrical busbars located on the elongate carrier behind the PV wafer dice, and electrically conductive connections made between the conductor elements and the busbars behind the PV wafer dice.

5. The PV receiver structure as claimed in claim 4 wherein the elongate carrier comprises a single-sided substrate and wherein the conductor elements and the busbars are both located on the first face of the elongate carrier.

6. The PV receiver structure as claimed in claim 4 wherein the elongate carrier comprises a double-sided substrate, wherein the busbars are located on a second, rearward, face of the elongate carrier and the electrically conductive connections between the conductor elements and the busbars are made through the elongate carrier.

7. The PV receiver structure as claimed in claim 6 wherein the elongate carrier comprises a flexible thermally conductive, electrically non-conductive substrate on which the conductor elements and busbars are formed as printed metallic regions.

8. The PV receiver structure as claimed in claim 6 wherein the electrodes on the first face of each PV wafer die extend transversely as fingers across the face of the die, and wherein the conductor elements on the first face of the elongate carrier are formed as metallic stripes that extend transversely across at least a portion of the transverse width of the elongate carrier.

9. The PV receiver structure as claimed in claim 7 wherein the electrodes on the first face of each PV wafer die extend transversely as fingers across the face of the die, and wherein the conductor elements on the first face of the elongate carrier are formed as metallic stripes that extend transversely across at least a portion of the transverse width of the elongate carrier.

10. The PV receiver structure as claimed in claim 8 wherein the electrodes on the first face of each PV wafer die are connected one-to-one with respective metallic stripes by solder connections.

11. The PV receiver structure as claimed in claim 9 wherein the electrodes on the first face of each PV wafer die are connected one-to-one with respective metallic stripes by solder connections.

12. The PV receiver as claimed in claim 6 wherein the electrically conductive connections between the conductor elements and the busbars are formed by vias.

13. The PV receiver as claimed in claim 7 wherein the electrically conductive connections between the conductor elements and the busbars are formed by vias.

14. The PV receiver as claimed in claim 4 when mounted to a thermally conductive elongate support member in the form of an elongate metal bar, to form a receiver assembly, the mounting being effected by bonding the elongate carrier to the elongate support member by a thermally conductive, electrically non-conductive adhesive.

15. The PV receiver as claimed in claim 5 when mounted to a thermally conductive elongate support member in the form of an elongate metal bar, to form a receiver assembly, the mounting being effected by bonding the elongate carrier to the elongate support member by a thermally conductive, electrically non-conductive adhesive.

16. The PV receiver as claimed in claim 6 when mounted to a thermally conductive elongate support member in the form of an elongate metal bar, to form a receiver assembly, the mounting being effected by bonding the elongate carrier to the elongate support member by a thermally conductive, electrically non-conductive adhesive.

17. The PV receiver as claimed in claim 7 when mounted to a thermally conductive elongate support member in the form of an elongate metal bar, to form a receiver assembly, the mounting being effected by bonding the elongate carrier to the elongate support member by a thermally conductive, electrically non-conductive adhesive.

18. The PV receiver as claimed in claim 8 when mounted to a thermally conductive elongate support member in the form of an elongate metal bar, to form a receiver assembly, the mounting being effected by bonding the elongate carrier to the elongate support member by a thermally conductive, electrically non-conductive adhesive.

19. The PV receiver as claimed in claim 9 when mounted to a thermally conductive elongate support member in the form of an elongate metal bar, to form a receiver assembly, the mounting being effected by bonding the elongate carrier to the elongate support member by a thermally conductive, electrically non-conductive adhesive.
